(19) United States
(12) Patent Application Publication
(10) Pub. No.: US 2006/0108693 A1
(43) Pub. Date: May 25, 2006

(54) Solder for fabricating solder bumps and pumping process

(76) Inventors: Yi-Hsiun Cheng, Hsinchu City (TW); Chia-Chieh Hu, Kaohsiung City (TW)

Correspondence Address: J C PATENTS, INC., 4 VENTURE, SUITE 250, IRVINE, CA, 92618, US

(21) Appl. No.: 11/231,265

(22) Filed: Sep. 19, 2005

(30) Foreign Application Priority Data
Sep. 22, 2004 (TW) 93128686

(51) Int. Cl. H01L 23/48

(52) U.S. Cl. 257/772

(57) ABSTRACT

A bumping process including following steps is disclosed. First, a wafer is provided, wherein the wafer has an active surface and bonding pads disposed on the active surface. Next, solder material is provided for forming solder posts on the bonding pads, wherein the solder material for forming the solder posts includes flux, alloy powder and organic solderability preservation material (OSP material). The OSP material encapsulates the surfaces of the alloy powder and is suitable for volatilizing in temperature between 210° C. and 240° C. Afterwards, the solder posts are reflowed to form solder bumps, so that the OSP material volatilizes. The solder material for fabricating solder bumps and the bumping process are capable of reducing the voids in the solder bumps probably produced after the solder posts are reflowed, which benefits to enhance reliability of the solder bump and the production yield of a bumping process.

### CROSS-REFERENCE TO RELATED APPLICATION

This application claims the priority benefit of Taiwan application serial no. 93128686, filed on Sep. 22, 2004. All disclosure of the Taiwan application is incorporated herein by reference.

### BACKGROUND OF THE INVENTION

1. Field of Invention

The present invention relates to solder material and a semiconductor manufacturing process, and particularly to solder material for fabricating solder bumps and a bumping process.

2. Description of the Related Art

As a widely used chip packaging technology, a flip-chip bonding technology (F/C bonding technology) can be briefly described as follows. A chip with a plurality of bonding pads arranged in area array on an active surface thereof is provided first. A plurality of solder bumps are then formed on the bonding pads of the chip. Afterwards, the chip is flipped such that the solder bumps formed on the chip are electrically and mechanically connected to a plurality of bump pads on a substrate or a PCB (printed circuit board). The F/C bonding technology is overwhelming in chip packages with high pin count, since it has a downsized packaging area and considerably short transmission paths. Today, the F/C bonding technology has been adopted in many applications already.

In order to bond a chip on the surface of the substrate or PCB through F/C bonding technology according to the prior art, a bumping process is performed first to form a plurality of solder bumps on an active surface of a chip. Generally, the bumping process may be performed by following steps, for example. First, a layer of stencil or a photosensitive film having a plurality of openings and used as a mask layer is formed on an active surface of a chip or a wafer in advance, wherein the bonding pads are exposed by the corresponded openings. Then, solder material is filled into the openings by printing, so that a plurality of solder posts are formed on the bonding pads. Thereafter, the above-described stencil or photosensitive film is removed such that the solder posts on the bonding pads are exposed. Finally, the solder posts are reflowed and cooled down to form a plurality of spherical solder bumps on the corresponded bonding pads.

The above-mentioned solder material for fabricating solder bumps is generally made of alloy powder as the major composition thereof. During reflowing, the alloy powder likely causes oxidation reaction and produces unwanted oxides and impurities. To remove the unwanted oxides and impurities, flux is often added in the solder material. However, the added flux may react with the oxides in the solder material or a polymer layer formed on the substrate and produce gas during refolwing. The gas such as vapor, the carbon dioxide (CO₂) or the like would form voids in the solder bumps after reflowing. Usually, flux with stronger deoxidizing capability is used to reduce oxidation of the alloy powder. The flux with stronger deoxidizing capability has a relatively high acidity, so that the residual flux after forming the spherical solder bumps may harm the solder bumps. As described above, reliability and production yield of solder bumps are affected by the voids formed in the solder bumps and the flux with stronger deoxidizing capability and high acidity.

### SUMMARY OF THE INVENTION

The present invention is directed to provide solder material for fabricating solder bumps with high reliability. The solder material is capable of reducing oxidation of the alloy powder thereof and reducing usage amount of the flux effectively.

The present invention is directed to provide a bumping process with a higher production yield. During the bumping process, solder bumps are formed by the solder material provided by the present invention, so that the voids generated during reflowing are significantly reduced.

As embodied and broadly described herein, the present invention provides a solder material for fabricating solder bumps. The solder material includes flux, alloy powder and organic solderability preservation material (OSP material), wherein the OSP material encapsulates the alloy powder and the OSP material is suitable for volatilizing in temperature between 210° C. and 240° C.

In an embodiment of the present invention, the material of the above-mentioned alloy powder includes lead-contained alloy or lead-free alloy, for example, tin-lead alloy or tin-silver-copper alloy. In addition, the OSP material can be expressed by the following chemical formula (1):

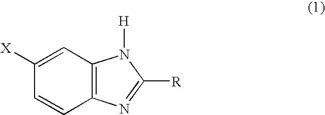

Wherein, R represents aryl or alkyl: C0˜C7 and X represents, for example, hydrogen (H), chlorine (Cl) or nitrogen dioxide (NO₂), for example.

As embodied and broadly described herein, the present invention further provides a bumping process including following steps. First, a wafer is provided, wherein the wafer has an active surface and a plurality of bonding pads disposed on the active surface. Next, solder material is provided for forming a plurality of solder posts on the bonding pads, wherein the solder material for forming the solder posts includes flux, alloy powder and organic solderability preservation material (OSP material). The OSP material encapsulates the surfaces of the alloy powder and is suitable for volatilizing in temperature between 210° C. and 240° C. Afterwards, the solder posts are reflowed to formed a plurality of solder bumps, so that the OSP material volatilizes.

In a preferable embodiment of the present invention, the method for forming solder posts can be described as follows. First, a mask layer having a plurality of openings is formed on a wafer, wherein the openings of the mask layer are used for exposing the bonding pads. Next, the solder material is filled into the openings for forming solder posts. Afterward, the mask layer is removed. The above-mentioned mask layer is, for example, a stencil or a patterned photosensitive film. Further, prior to forming the solder posts, for example, an under bump metallurgy layer is formed on each bonding pad, respectively.

In the solder material of the present invention, the surfaces of the alloy powder is encapsulated by the organic solderability preservation material (OSP material), such that the alloy powder is isolated from the atmosphere and the alloy powder is prevented from oxidation substantially. The OSP material would volatilize after a high-temperature process (reflowing) without being remained in the solder. By utilizing the OCP material, the usage amount of the flux is effectively reduced, the voids generated inside the solder bumps probably produced after reflowing can be significantly decreased. In addition, the OCP material can work with flux having low acidity to enhance reliability of the solder bump and the production yield of the bumping process.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve for explaining the principles of the invention.

FIG. 1A˜FIG. 1F are diagrams showing the sequent steps of a bumping process of the present invention.

### DESCRIPTION OF THE EMBODIMENTS

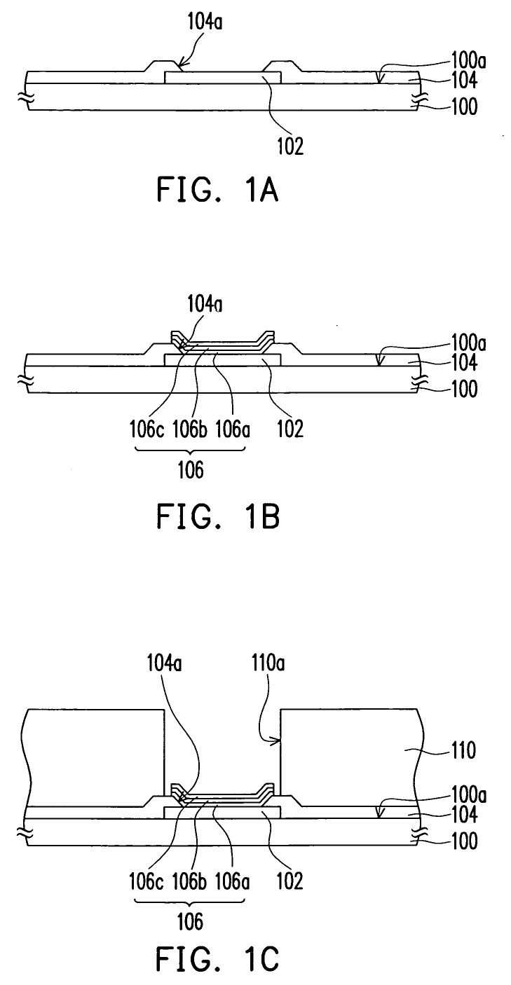

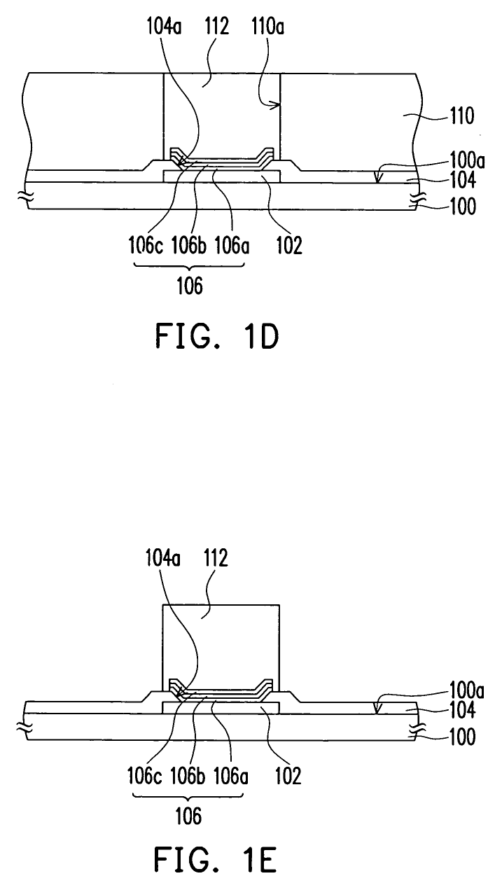

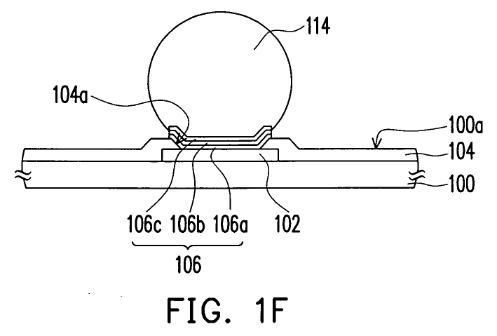

FIG. 1A˜FIG. 1F are diagrams showing the sequent steps of a bumping process of the present invention.

Referring to FIG. 1A, a wafer 100 is provided first. The wafer 100 has an active surface 100a, on which a plurality of bonding pads 102 (only one is shown in the FIG. 1A) and a passivation layer 104 are disposed. The passivation layer 104 covers the active surface 100a of the wafer 100 and the bonding pads 102 are exposed by the openings 104a of the passivation layer 104. In an embodiment, the material of the bonding pads 102 is, for example, aluminum (Al) or copper (Cu), while the material of the passivation layer 104 is, for example, silicon nitride (SiNx) or the like.

Next referring to FIG. 1B, an under bump metallurgy layer 106 is formed on each bonding pad 102, respectively. The under bump metallurgy layer 106 includes, for example, an adhesion layer 106a, a barrier layer 106b and a wetting layer 106c. As shown in FIG. 1B, the adhesion layer 106a is disposed on the surface of the bonding pad 102 and made of, for example, titanium (Ti), aluminum (Al) or tantalum (Ta). The barrier layer 106b is disposed on the adhesion layer 106a and made of, for example, nickel-vanadium alloy. The wetting layer 106c is disposed on the barrier layer 106b and made of, for example, copper. The method for forming the above-described adhesion layer 106a, barrier layer 106b and wetting layer 106c is, for example, sputtering or evaporation. In a preferrable embodiment, while the bonding pad 102 is made of aluminum, the stacking structure of the under bump metallurgy layer 106 containing an adhesion layer 106a, a barrier layer 106b and a wetting layer 106c is preferably composite by, for example, aluminum/nickel-vanadium alloy/copper (Al/NiV/Cu). While the bonding pad 102 is made of copper, the stacking structure of the under bump metallurgy layer 106 containing an adhesion layer 106a, a barrier layer 106b and a wetting layer 106c is preferably composite by, for example, titanium/nickel-vanadium alloy/copper (Ti/NiV/Cu).

Referring to FIG. 1C, a mask layer 110 is formed on the wafer 100, wherein the mask layer 110 has a plurality of openings 110a (only one is shown in FIG. 1C) used for exposing the under bump metallurgy layer 106 on the bonding pad 102. In an embodiment, the mask layer 110 is a stencil and made of metal, for example. In another embodiment, the mask layer 110 can be a patterned photosensitive film made of, for example photoresist material. The mask layer 110 is formed by entirely coating a photoresist material layer (not shown in the figure) on the wafer 100 and patterning the photoresist material layer by photolithography and developing process.

Further referring to FIG. 1D, the solder material is filled into the openings 110a of the mask layer 110 for forming solder posts 112 by printing or other process. Remarkably, the solder material used in the present invention includes flux, alloy powder and organic solderability preservation material (OSP material). The material of the alloy powder is, for example, lead-contained tin-lead alloy or lead-free tin-silver-copper alloy. In addition, the OSP material encapsulates the surfaces of the alloy powder for isolating the alloy powder from the atmosphere. In an embodiment, the OSP material can be expressed by the following chemical formula (1): 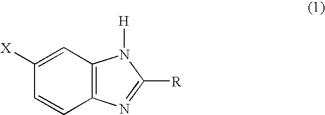
Where, R represents, for example, aryl or alkyl: C0˜C7, X represents, for example, hydrogen (H), chlorine (Cl) or nitrogen dioxide (NO₂) and the OSP material is suitable for volatilizing in temperature between 210° C. and 240° C.

Further referring to FIG. 1E, the mask layer 110 is then removed. If the mask layer 110 is a stencil, the mask layer 110 can be directly removed from the wafer 100; if the mask layer 110 is a photosensitive film, the mask layer 110 can be removed by using etchant or the like.

Furthermore referring to FIG. 1F, a reflowing process is performed. Since the processing temperature during the reflowing process is higher than the volatilizing temperature range between 210° C. and 240° C., therefore the OSP material would be volatilized during the reflowing process and the solder posts 112 is reflowed to form spherical solder bumps 114.

Remarkably, the processing sequence in the other embodiments of the present invention can be optionally altered this way, that is a reflowing process is performed to primarily form spherical solder bumps 114 first, followed by removing the mask layer 110. Besides, after removing the mask layer 110, another process of reflowing the solder bumps can be further performed to strengthen the mechanical strength of the solder bump 114.

From the above described, it can be seen that the solder alloy powder of the present invention are encapsulated by organic solderability preservation material (OSP material) to insulate the alloy powder from the atmosphere for avoiding oxidation substantially. After the reflowing, the OSP material is not residual in the solder bumps since the OSP material is volatilized at a high-temperature. In this way, not only the usage amount of the flux in the solder material is effectively reduced, but also the voids generated in the solder bumps probably produced after the reflowing is decreased. Besides, since the alloy powder gets a pretty good anti-oxidation protection in the present invention, the restricted oxygen-content in a reflowing oven allows to be relatively increased, which leads to reduce the nitrogen gas usage and save the production cost. In other words, the solder material for fabricating solder bumps and the bumping process benefit to enhance reliability of the solder bump and the production yield and save the production cost.

The foregoing description of the preferred embodiment of the present invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A solder material for fabricating solder bumps, mainly comprising:
flux;
alloy powder; and
organic solderability preservation material (OSP material), used for encapsulating the alloy powder.

2. The solder material for fabricating solder bumps as recited in claim 1, wherein the material of the alloy powder comprises lead-contained alloy or lead-free alloy.

3. The solder material for fabricating solder bumps as recited in claim 1, wherein the material of the alloy powder comprises tin-lead alloy or tin-silver-copper alloy.

4. The solder material for fabricating solder bumps as recited in claim 1, wherein the chemical formula (1) of the OSP material is: 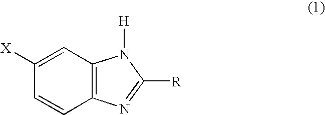
wherein, R comprises aryl or alkyl: C0˜C7 and X comprises hydrogen (H), chlorine (Cl) or nitrogen dioxide (NO₂).

5. The solder material for fabricating solder bumps as recited in claim 1, wherein the OSP material is suitable for volatilizing in temperature between 210° C. and 240° C.

6. A bumping process, comprising:
providing a wafer having an active surface and a plurality of bonding pads disposed on the active surface;
providing a solder material for forming a plurality of solder posts on the bonding pads wherein the solder material comprises flux, alloy powder and organic solderability preservation material (OSP material) for encapsulating the alloy powder; and
reflowing the solder posts for volatilizing the OSP material to form a plurality of solder bumps.

7. The bumping process as recited in claim 6, wherein the method for forming the solder posts comprises:
providing a mask layer having a plurality of openings on the wafer, wherein the openings of the mask layer are used for exposing the bonding pads;
filling the solder material into the openings for forming the solder posts; and
removing the mask layer.

8. The bumping process as recited in claim 6, wherein the mask layer comprises a stencil or a patterned photosensitive film.

9. The bumping process as recited in claim 6, further comprising forming an under bump metallurgy layer on each of the bonding pads respectively before forming the solder posts.

10. The bumping process as recited in claim 6, wherein the OSP material is suitable for volatilizing in temperature between 210° C. and 240° C.
